(19) United States
(12) Patent Application Publication
(10) Pub. No.: US 2001/0051214 A1
(43) Pub. Date: Dec. 13, 2001

(54) Apparatus and method for vapor deposition

(76) Inventor: Keiichirou Tahara, Tokyo (JP)

Correspondence Address: YOUNG & THOMPSON, 745 SOUTH 23RD STREET 2ND FLOOR, ARLINGTON, VA, 22202

(21) Appl. No.: 09/811,397

(22) Filed: Mar. 20, 2001

(30) Foreign Application Priority Data
Mar. 21, 2000 (JP) 2000-078511

(51) Int. Cl. C23C 16/00

(52) U.S. Cl. 427/248.1; 118/715

(57) ABSTRACT

The present invention is a vapor deposition apparatus comprising a cylindrical outer reaction tube closed on an upper end thereof; a cylindrical inner reaction tube which is disposed inside the outer reaction tube and which accommodates the loading of a stack of semiconductor substrates; a first manifold which supports the outer reaction tube and has a first injector which introduces reaction gases between the outer reaction tube and the inner reaction tube; and a second manifold which supports the first manifold and the inner reaction tube and has a second injector which introduces reaction gases into the inner reaction tube.

### BACKGROUND OF THE INVENTION

1. Field of the Invention

This invention relates to a vapor deposition apparatus and a vapor deposition method.

2. Description of Related Art

Chemical vapor deposition (CVD) is known as a vapor deposition method, and is used in a semiconductor manufacturing process or the like.

FIG. 4 shows an example of a reaction chamber of a vertical low pressure CVD apparatus. As shown in FIG. 4, the reaction chamber provides two vertical set reaction tubes, a cylindrical outer reaction tube 21 closed on an upper end thereof (an outer tube 1) and a cylindrical inner reaction tube 22 (an inner tube 22) which arranged in the outer tube 21 and accommodates loading a stack of semiconductor wafers 23. These semiconductor wafers 23 are introduced into the inner tube 22 from the lower portion. A heat insulating tube 24 is provided under the stack of semiconductor wafers 23, and both are mounted on a boat table 27. The boat table 27 is fixed on a hatch 28. Moreover, a heater 32 for heating the entire reaction chamber is provided outside the outer tube 21.

The outer tube 21 and the inner tube 22 are supported by a ring-shaped manifold 25 at the lower portion thereof. The manifold 25 comprises injectors 26 which introduce reaction gases into the reaction chamber, and an exhaust port 31 which is connected to an evacuator (not shown in FIG. 4), exhausts gases from the reaction chamber, and keeps the internal pressure of the reaction chamber lower than the external pressure.

An opening port of the injectors 26 is formed inside the inner tube 22 and/or between the inner tube 22 and the outer tube 21. The injectors 26 have various flow routes according to the kind of layers to be formed on the wafers 23. With such a structure, it is possible to change the kind of reaction gases and flow routes of the reaction gases. Further, the injectors 26 are fixed in holes which are provided in the manifold 25. Through the injectors 26, the reaction chamber is contacted to the outside thereof.

FIG. 5 is an enlarged view of a portion around the manifold 25 of FIG. 4.

In this reaction chamber, as shown in FIG. 5, two injectors 26 are provided in the manifold 25: the first injector 26A has an opening portion provided between the inner tube 22 and the outer tube 21, and the second injector 26B has an opening portion provided inside the inner tube 22.

As shown in FIG. 5, a ring-shaped holder 22A is provided at the lower portion of the inner tube 22. The holder 22A has a smaller inside diameter than that of the inner tube 22 and supports the inner tube 22. Moreover, the holder has more than three projections for fixing on the manifold 25 on an outer side thereof.

The inner tube 22 is fixed on a supporting portion 29A of the manifold 25 by the holder 22A. The supporting portion 29A has a hole through which the holder 22A can pass. In the process of fixing the inner tube 22, the holder 22A is passed through the hole of the supporting portion 29A; next the holder 22A is horizontally turned to the position at which the projections of the holder 22A are mounted on the supporting portion 29A; then this supporting portion 29A is fixed by a fixing part 30 from the opposite side of the holder 22A by at least a screw. The outer tube 21 is fixed on the manifold 25 by a fixing part 21A.

In this type of CVD apparatus, the inner tube 22 is periodically removed from the reaction chamber and washed to remove the reaction by-product adhering to the inside wall of the inner tube 22 after several processes of film forming.

In this case, in the CVD apparatus as shown in FIGS. 4 and 5, the process to remove the inner tube 22 from the reaction chamber takes many steps because the fixing structure of the inner tube 22 is very complicated as mentioned above.

In the removing process of the inner tube 22, first, the second injector 26A is removed from the manifold 25, and then the fixing part 30 is removed from the supporting portion 29A. Next, the holder 22A is removed from the supporting portion 29A by turning the inner tube 22. Then the inner tube 22 is removed from the reaction chamber. These processes are very dangerous and decrease the efficiency of the CVD apparatus.

On the other hand, in the forming process of the thin film by the CVD apparatus, it is very important to prevent contamination by minute particles, and many measures for preventing contamination by the particles have been taken up to the present. In recent years, as the manufacturing technology of semiconductor devices has become very minute, the particle diameters have become smaller and smaller. Further, these very minute particles, which have not been a problem in the past, are beginning to the causes various problems in the forming process of films in the CVD apparatus.

However, in the above CVD apparatus, these very minute particles are produced after the exchanging process of the inner tube 2.

These particles are produced by reaction by-products when the inner tube 22 is exchanged at normal temperatures. These reaction by-products are produced when the inner temperature of the reaction chamber changes from a high temperature to a low temperature. Therefore, the inner tube 22 must be exchanged at a high-temperature state which is the same temperature state at the time of removing wafers on which films are formed from the reaction chamber, for example 400° C., and not at a normal temperature state, in order to prevent the production of very minute particles.

However, in the above CVD apparatus, it is difficult to exchange the inner tube 22 at a high temperature because of the complicated fixing structure of the inner tube 22.

### SUMMARY OF THE INVENTION

In view of the above situation, it is an object of the present invention is to provide a vapor deposition apparatus and method in which the inner tube can be exchanged safely and easily while keeping the chamber at a high temperature and production of very minute particles can be prevented without decreasing the efficiency of the vapor deposition apparatus.

The vapor deposition apparatus of the present invention comprises a cylindrical outer reaction tube closed on an upper end thereof; a cylindrical inner reaction tube which is disposed inside the outer reaction tube and which accommodates the loading of a stack of semiconductor substrates; a first manifold which supports the outer reaction tube and has a first injector which introduces reaction gases between the outer reaction tube and the inner reaction tube; and a second manifold which supports the first manifold and the inner reaction tube and has a second injector which introduces reaction gases into the inner reaction tube.

According to the vapor deposition apparatus of the present invention, since the vapor deposition apparatus has two manifolds capable of separating, it is easy to separate the second manifold supporting the inner tube from the first manifold supporting the outer tube. Therefore, it is possible to exchange the inner tube at a high temperature. As a result, very minute particles are not produced in the removing process of the inner reaction tube and the efficiency of the apparatus is not decreased.

Specifically, in the vapor deposition apparatus of the present invention, an exhaust port is provided in the first manifold.

Moreover, the first manifold and the second manifold are connected to each other by at least a screw.

Moreover, a lower end of the inner reaction tube is supported by a supporting portion of the second manifold.

Furthermore, the first manifold and the second manifold are made of stainless steel.

The vapor deposition method according to the present invention uses the vapor deposition apparatus as described above and comprises forming films on the semiconductor substrates accommodated in the inner reaction tube by vapor deposition at a predetermined temperature; removing the semiconductor substrates from the inner reaction tube; removing the second manifold from the first manifold, and removing the second manifold and the inner reaction tube from the outer reaction tube without substantially cooling the outer reaction tube; and washing the second manifold and the inner reaction tube.

According to the vapor deposition apparatus of the present invention, since the fixing structure of the inner tube of the vapor deposition apparatus is not complicated, it is easy to remove the inner tube from the outer tube. Therefore, it is possible to exchange the inner tube while keeping the chamber at a high temperature without the production of very minute particles. As a result, it is possible to raise the efficiency of the vapor deposition method. Moreover, the exchanging process is easy and safe.

A vapor deposition maintenance method using the vapor deposition apparatus according to the present invention comprises removing the semiconductor substrates from the inner reaction tube; removing the second manifold from the first manifold, and removing the second manifold and the inner reaction tube from the outer reaction tube without substantially cooling the outer reaction tube; and washing the second manifold and the inner reaction tube.

According to the maintenance method of the present invention, since the removing process of the inner tube is safe and easy, it is possible to exchange the inner tube at a high temperature. Therefore, it is possible to prevent the production of very minute particles and to raise the efficiency of the vapor deposition method.

### BRIEF DESCRIPTION OF THE DRAWINGS

FIG. 1 is a partial cross-sectional view showing a portion around the manifolds of a CVD apparatus according to one embodiment of the present invention.

FIG. 2 is a partial cross-sectional view showing a situation where the second manifold is separated from the first manifold in the CVD apparatus of FIG. 1.

FIG. 3 is a cross-sectional view showing a reaction chamber of a vertical low pressure CVD apparatus according to one embodiment of the present invention.

FIG. 4 is a cross-sectional view showing one embodiment of a reaction chamber of a vertical low pressure CVD apparatus according to the prior art.

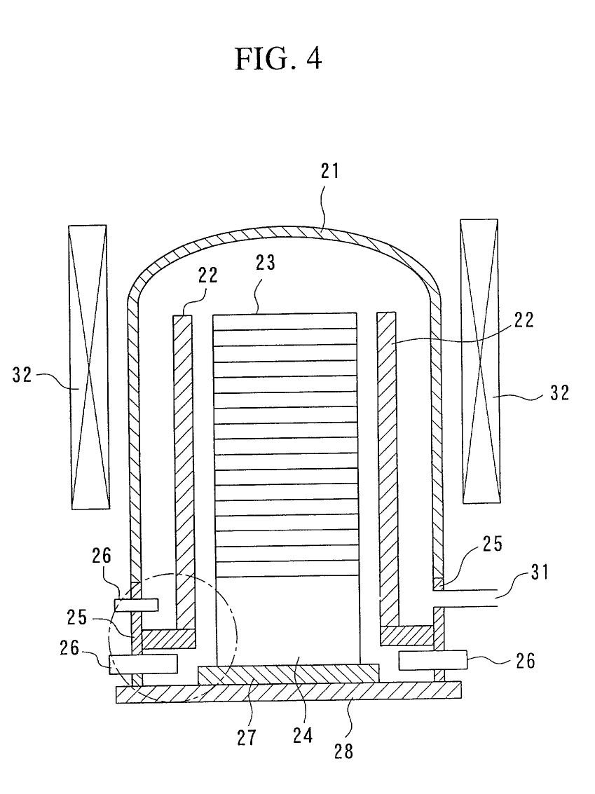

FIG. 5 is a partial cross-sectional view of a portion around the manifold of CVD apparatus according to the prior art.

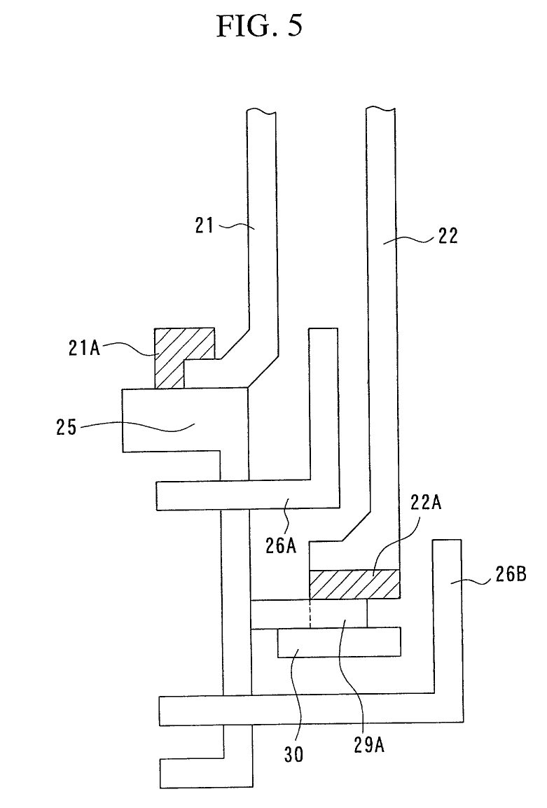

### DETAILED DESCRIPTION OF THE INVENTION

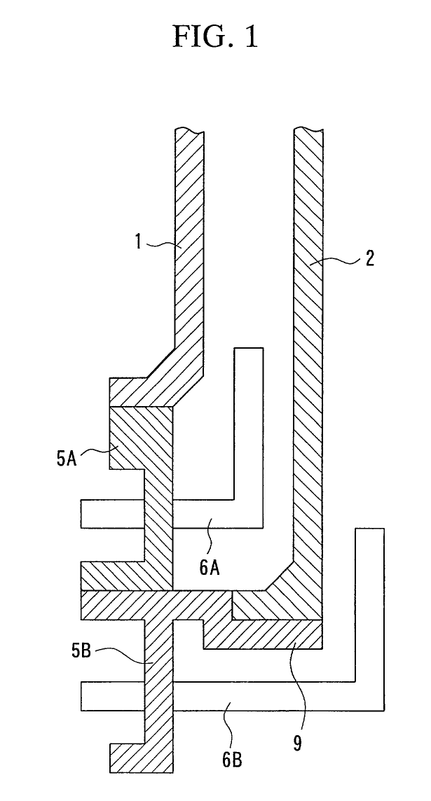

Hereinafter, the vapor deposition apparatus and the vapor deposition method according to an embodiment of the present invention will be explained with reference to FIGS. 1 to 3. However, the present invention is not limited to this embodiment, and includes various modifications.

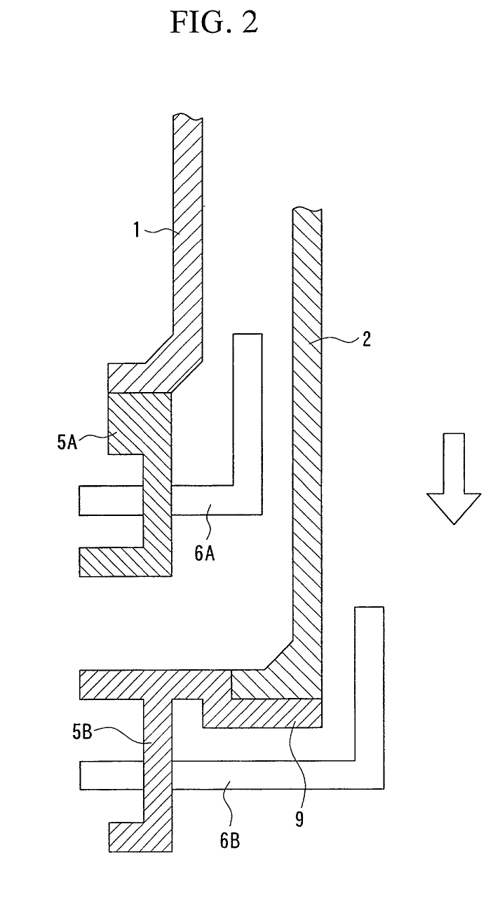

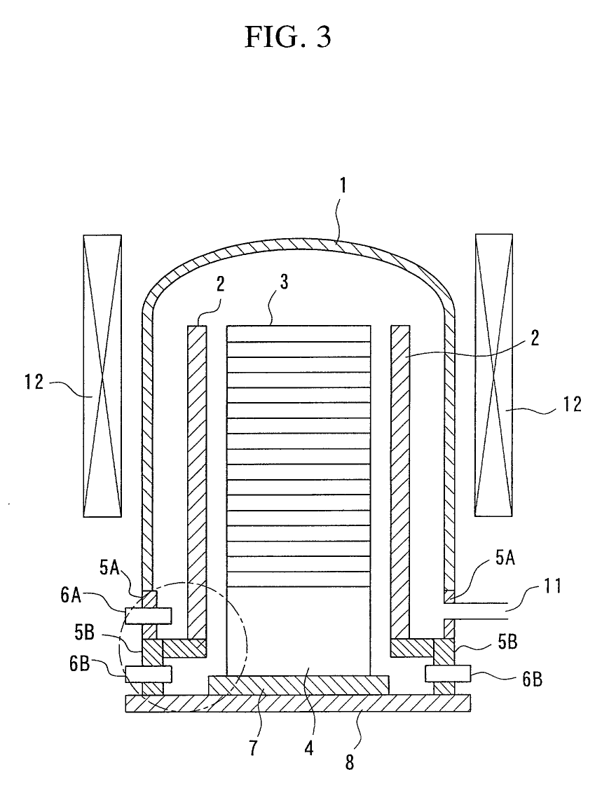

FIG. 1 is a partial cross-sectional view showing a portion around the manifold according to one embodiment of the present invention. FIG. 2 is a partial cross-sectional view showing a situation where the second manifold is separated from the first manifold. FIG. 3 is a cross-sectional view showing a reaction chamber of a vertical low pressure CVD apparatus according to one embodiment of the present invention.

This CVD apparatus comprises a reaction chamber comprising two vertical set reaction tubes and two separable manifolds.

A cylindrical outer tube 1 is closed on the upper end thereof and a cylindrical inner tube 2 is disposed inside the outer tube 1 and accommodates the loading of a stack of semiconductor wafers 3.

The outer tube 1 is supported by a ring-shaped first manifold 5A from the lower portion thereof. The first manifold 5A has a first injector 6A which introduces reaction gases between the outer tube 1 and the inner tube 2. The first manifold 5A is connected to a ring-shaped second manifold 5B on a lower portion, and is supported by the second manifold 5B.

The second manifold 5B has a second injector 6B which introduces reaction gases into the inner tube 2. The inner tube 2 is supported by a supporting portion 9 of the second manifold 5B.

The first manifold 5A and the second manifold 5B are made of stainless steel and the like. If the first and second manifolds are made of stainless steel, they have superior corrosion resistance and strength.

The second manifold 5B is connected to the first manifold 5A by at least a screw. If the fixing structure is at least a screw, the second manifold 5B is easily separated from the first manifold 5A.

Moreover, in this CVD apparatus, an exhaust port 11 is provided in the first manifold 5A. Since the exhaust port 11 is provided in the first manifold 5A, it is easy to separate the second manifold 5B from the first manifold 5A.

Furthermore, a heat insulating tube 4 is provided under the stack of semiconductor wafers 3. The stack of semiconductor wafers 3 and the heat insulating tube 4 are mounted on a boat table 7. The boat table 7 is fixed in a hatch 8. Moreover a heater 12 for heating the entire reaction chamber is provided outside the outer tube 1.

Hereinafter, an embodiment of the vapor deposition method using the above described CVD apparatus according to the present invention is described.

This embodiment shows a case of forming a nitrogen film on the semiconductor wafers 3. In this case, the nitrogen film is formed at a predetermined temperature, for example, 600 to 800° C., by using NH₃ and SiF₄ as the reaction gases. Next, after the temperature in the reaction chamber is decreased to about 400° C., the stack of semiconductor wafers 3 having a nitrogen film is removed from the inner tube 2. Next, the second manifold 5B is removed from the first manifold 5A without substantially cooling the outer tube 1 ( the reaction chamber ). Next, the new second manifold and the inner tube that have already been washed are introduced into the outer tube 1, and the forming film process of the semiconductor wafers 3 is continued. Then, the second manifold 5B and the inner tube 2 are washed after they have been removed from the outer tube 1.

In the above-described embodiment, a description was given for the case of a reaction chamber of a vertical type low pressure CVD apparatus. However, this construction of the reaction chamber is equally suitable with other types of vapor deposition apparatus.

Moreover, in the above-described embodiment, a description was given for the case of forming a nitrogen film on the semiconductor wafers 3. However, the method is capable of applying the steps for forming other kinds of films on the semiconductor substrates, for example, forming an oxidation film or a silicon film.

As described above in detail, the present invention has the effect described below.

Since the apparatus has a simple structure which is capable of separating the first manifold 5A and the second manifold 5B, it is possible to exchange the inner tube 2 at a high temperature. As a result, no very minute particles are produced in the exchanging process of the inner tube 2. Moreover this exchanging process is safe and does not reduce the work efficiency of the apparatus.

1. A vapor deposition apparatus comprising:
a cylindrical outer reaction tube closed on an upper end thereof;
a cylindrical inner reaction tube which is disposed inside the outer reaction tube and which accommodates the loading of a stack of semiconductor substrates;
a first manifold which supports the outer reaction tube and has a first injector which introduces reaction gases between the outer reaction tube and the inner reaction tube; and
a second manifold which supports the first manifold and the inner reaction tube and has a second injector which introduces reaction gases into the inner reaction tube.

2. A vapor deposition apparatus according to claim 1, wherein an exhaust port is provided in the first manifold.

3. A vapor deposition apparatus according to claim 1, wherein the first manifold and the second manifold are connected to each other by at least a screw.

4. A vapor deposition apparatus according to claim 1, wherein a lower end of the inner reaction tube is supported by a supporting portion of the second manifold.

5. A vapor deposition apparatus according to claim 1, wherein the first manifold and the second manifold are made of stainless steel.

6. A vapor deposition method using the vapor deposition apparatus according to claim 1 comprising:
forming films on the semiconductor substrates accommodated in the inner reaction tube by vapor deposition at a predetermined temperature;
removing the semiconductor substrates from the inner reaction tube;
removing the second manifold from the first manifold, and removing the second manifold and the inner reaction tube from the outer reaction tube without substantially cooling the outer reaction tube; and
washing the second manifold and the inner reaction tube.

7. A vapor deposition maintenance method using the vapor deposition apparatus according to claim 1 comprising:
removing the semiconductor substrates from the inner reaction tube;
removing the second manifold from the first manifold, and removing the second manifold and the inner reaction tube from the outer reaction tube without substantially cooling the outer reaction tube; and
washing the second manifold and the inner reaction tube.
